(19) United States
(12) Patent Application Publication
(10) Pub. No.: US 2013/0076455 A1
(43) Pub. Date: Mar. 28, 2013

(54) MODULARIZED SIGNAL FILTER

(71) Applicant: Shao Pai Chen, Taipei City (TW)

(72) Inventor: Shao Pai Chen, Taipei City (TW)

(21) Appl. No.: 13/244,602

(22) Filed: Sep. 25, 2011

(51) Int. Cl. H03H 7/01

(52) U.S. Cl. 333/181; 333/185

(57) ABSTRACT

A signal filter includes a main ferrite core module and a sub ferrite core module. The main ferrite core module having a first base, a first cover, a plurality of first ferrite cores, a plurality of first terminals and a recess disposed inside. The sub ferrite core module having a second base, a second cover, a plurality of second ferrite cores, and a plurality of second terminals, capable of being assembled with the main ferrite core module. The signal filter is assembled with the main and sub ferrite core module, and first and second terminals are parallel disposed on two sides.

### BACKGROUND OF THE INVENTION

1. Field of the Invention

The present invention relates to a modularized signal filter, and more particularly to a modularized signal filter that capable of reducing interference of the signals.

2. Description of the Related Art

Currently, ferrite cores are modularized to improve the manufacturing process and the number of ferrite cores. As shown in FIGS. 1 and 2, a signal filter 1 utilizes an upper base 10 and a lower base 13 of a PCB (Printed circuit board) as a carried body, and the ferrite core modules 11, 11′ and the terminal modules 12 are connected with each other through many connecting wires on the PCB. When the signal filter is operating, the magnetic waves generated by the device and the variety and difference of the connecting wires on PCB can all effect the quality of the filtered signals.

Therefore, it is desirable to provide a modularized signal filter to mitigate and/or obviate the aforementioned problems.

### SUMMARY OF THE INVENTION

An objective of the present invention is to provide modularized signal filter which provides a mating engagement assembly to reduce the noise of the filtered signals.

A characteristic of an embodiment of the present invention is, the main ferrite core module has a plurality through apertures.

Another characteristic of an embodiment of the present invention is, the main ferrite core module has a recess on a top face and a bottom face.

Another characteristic of an embodiment of the present invention is, the sub ferrite core module has a plurality of through aperture

Another characteristic of an embodiment of the present invention is, the sub ferrite core module has a recess on a bottom face.

Another characteristic of an embodiment of the present invention is, the recesses on the top faces of the main and sub ferrite core module are used for accepting the plurality of ferrite cores.

Other objects, advantages, and novel features of the invention will become more apparent from the following detailed description when taken in conjunction with the accompanying drawings.

### BRIEF DESCRIPTION OF THE DRAWINGS

FIG. 1 is a perspective schematic v of a prior art signal filter.

FIG. 2 is an exploded schematic drawing of the prior art signal filter.

FIG. 3 is a perspective schematic drawing of a modularized signal filter of an embodiment according to the present invention.

FIG. 4 is an exploded schematic drawing of the modularized signal filter of an embodiment according to the present invention.

FIG. 5 is another exploded schematic drawing of the modularized signal filter of an embodiment according to the present invention.

FIG. 6 is a cross-sectional view of the modularized signal filter of a embodiment according to the present invention.

FIG. 7 is a combination cross-sectional view of the modularized signal filter of embodiment according to the present invention.

FIG. 8 is a cross-sectional view of a ferrite core module of the modularized signal filter of embodiment according to the present invention.

FIG. 9 is a schematic drawing of a ferrite core module of the modularized signal filter of embodiment according to the present invention.

FIG. 10 is another schematic drawing of a ferrite core module of the modularized signal filter of embodiment according to the present invention.

FIG. 11 is another schematic drawing of a ferrite core module of the modularized signal filter of embodiment according to the present invention.

FIG. 12 is a schematic drawing of a dummy-proof mechanism of the modularized signal filter of embodiment according to the present invention.

FIG. 13 is another schematic drawing of a dummy-proof mechanism of the modularized signal filter of embodiment according to the present invention.

FIG. 14 is a schematic drawing of the signal filter having a different width X.

FIG. 15 is an assembly option of the modularized signal filter of embodiment according to the present invention.

FIG. 16 is another assembly option of the modularized signal filter of embodiment according to the present invention.

FIG. 17 is another assembly option of the modularized signal filter of embodiment according to the present invention.

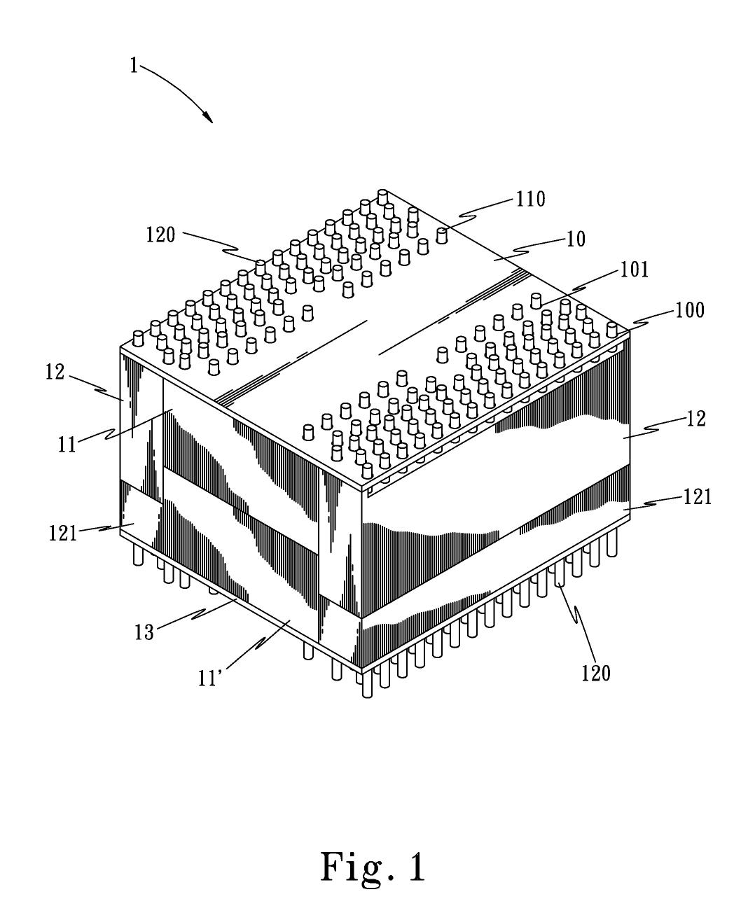

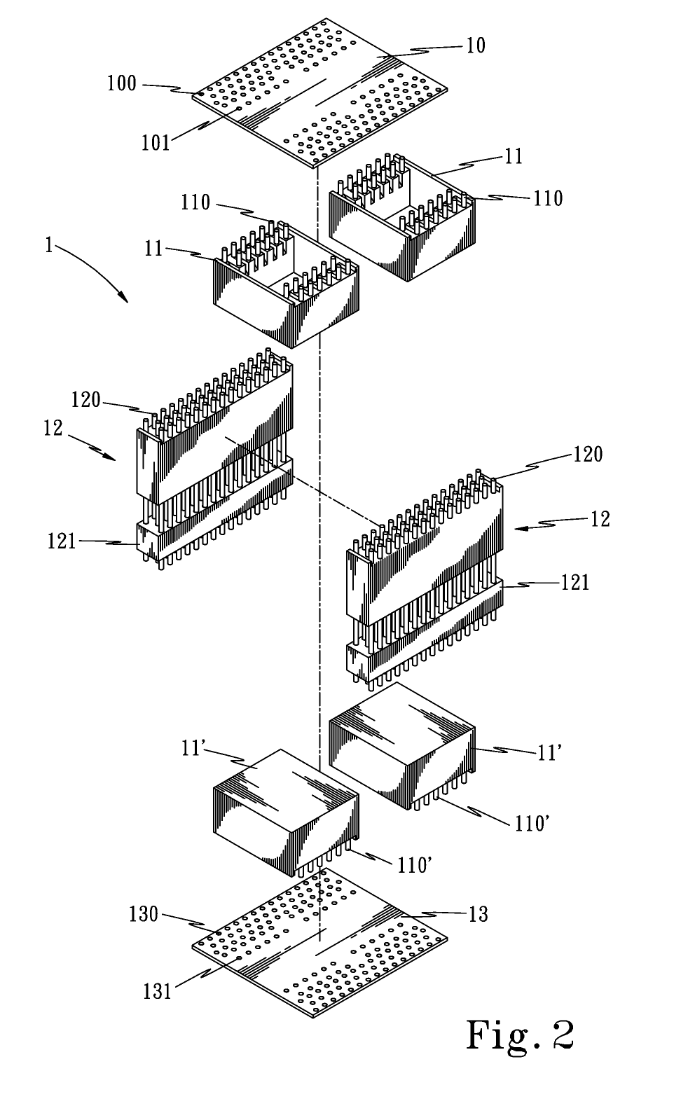

### DETAILED DESCRIPTION OF THE PREFERRED EMBODIMENT

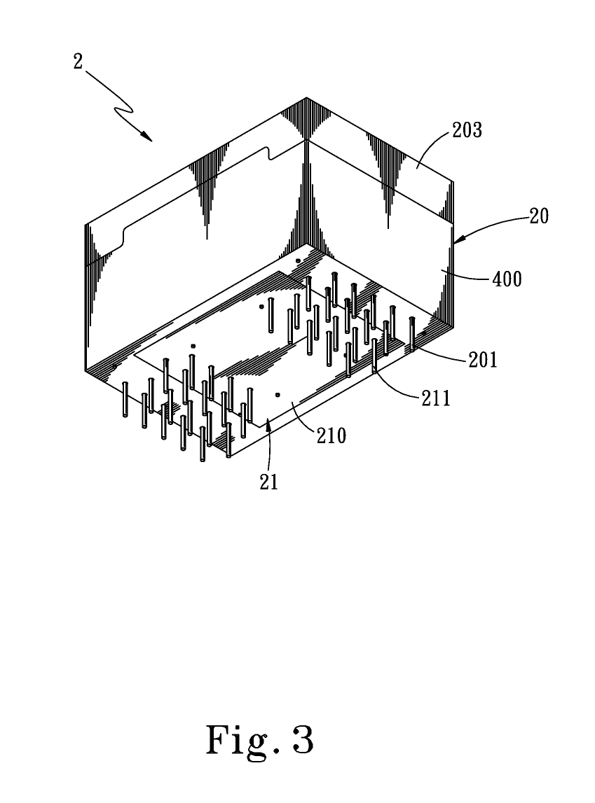

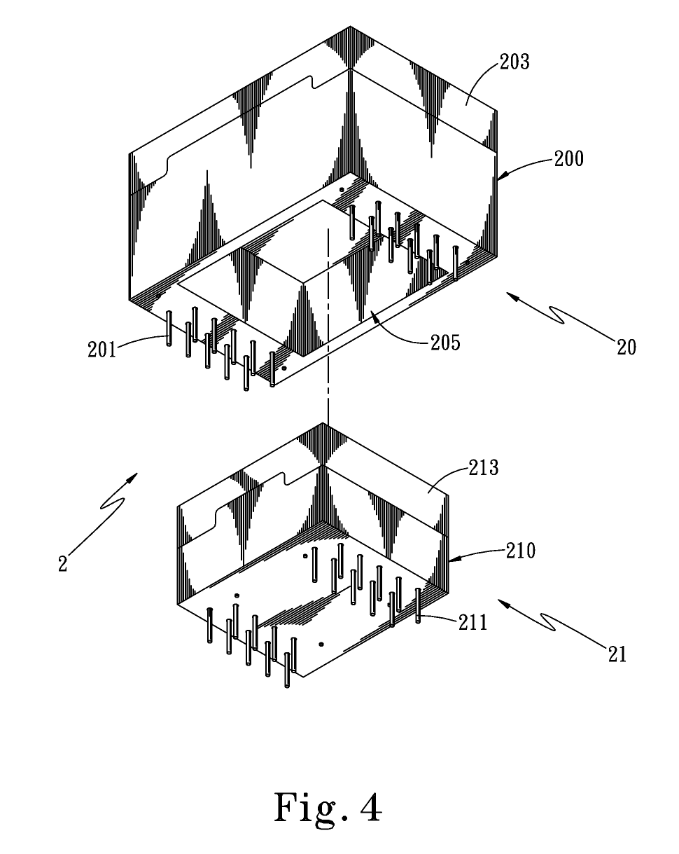

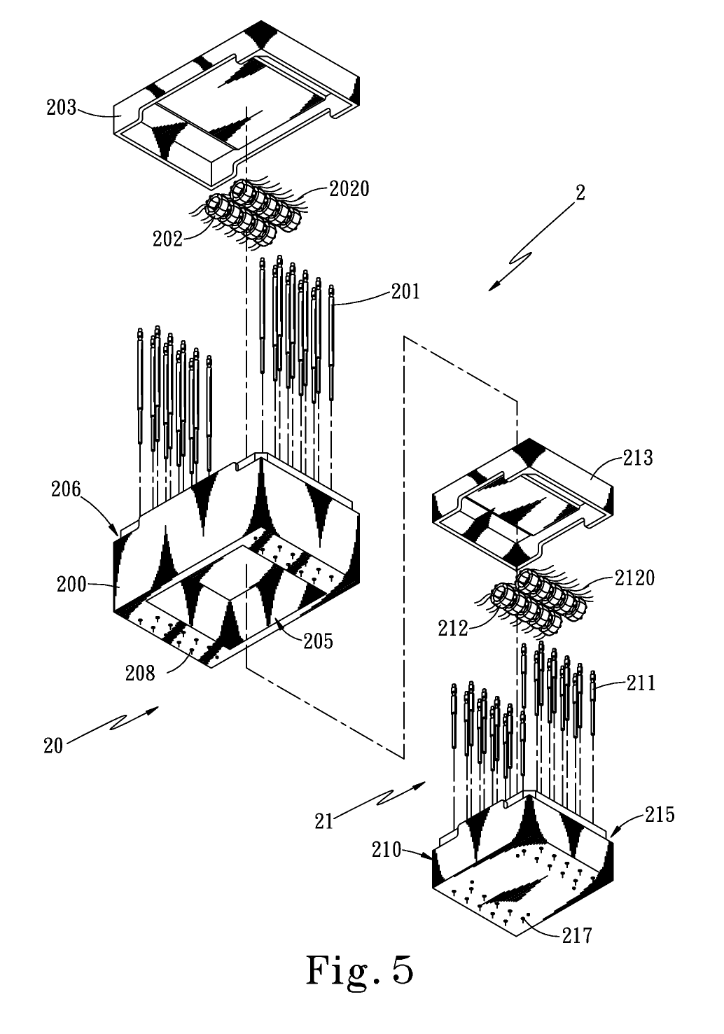

First, please refer to FIG. 3, FIG. 4 and FIG. 5. FIG. 3 is a perspective schematic drawing of a modularized signal filter of an embodiment according to the present invention. FIG. 4 is an exploded schematic drawing of the modularized signal filter of an embodiment according to the present invention. FIG. 5 is another exploded schematic drawing of the modularized signal filter of an embodiment according to the present invention. A signal filter 2 comprises a main ferrite core module 20 and a sub ferrite core module 21. The main ferrite core module 20 comprises a first base 200, a plurality of first terminals 201, a plurality of first ferrite cores 202 and a first cover 203. The sub ferrite core module 21 comprises a second base 210, a plurality of second terminals 211, a plurality of second ferrite cores 212, and a second cover 213.

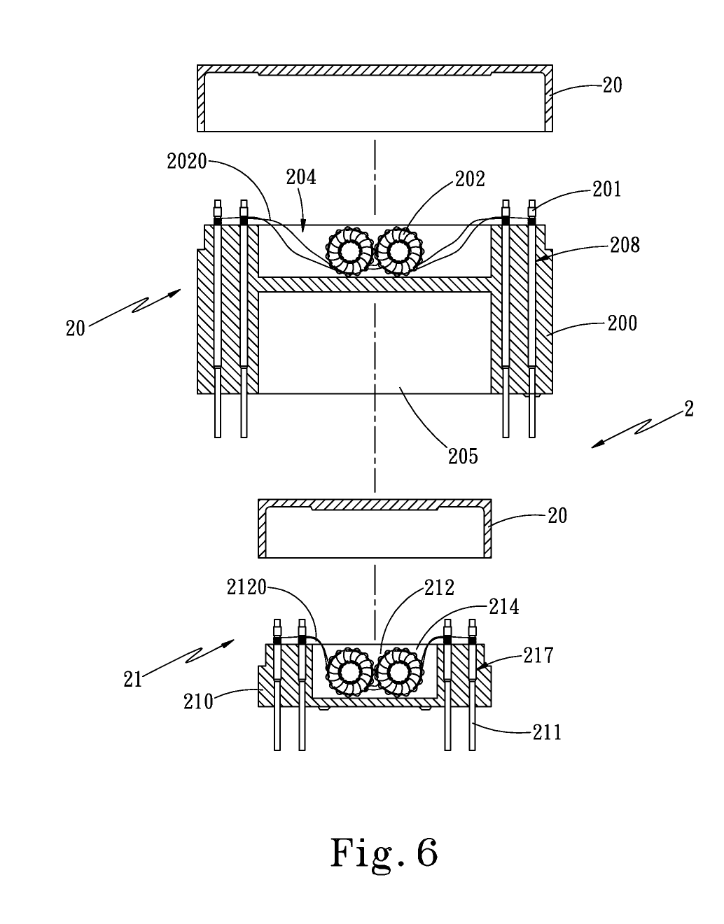

The first base 200 of the main ferrite core module 20 has a approximately rectangular block shape and two rectangular first recesses 204, 205 respectively disposed at an upper face and a lower face (please refer FIG. 6). There are a plurality of through apertures 208 disposed at two sides of both of the first recesses 204, 205, and an first engaging groove 206 is respectively formed at two side edges of the upper face for being engaged with the first cover 203. Moreover, the first recess 204 of the first base 200 is used for accepting the first ferrite core 202, and the first recess 205 is used for accepting the sub ferrite core module 21. The through aperture 208 is used for accepting the plurality of first terminals 201, and the first terminals 201 are placed through the through apertures 208 and wrapped by conducting wires 2120 between the first ferrite core 202. The first cover 203 is a U-shaped rectangle body and engages with the first engaging groove 206 of the first base 200.

Furthermore, the second base 210 of the sub ferrite core module 21 has a approximately rectangular block shape and a rectangular second recesses 214, disposed at an upper face (please refer FIG. 6). There are a plurality of through apertures 217 disposed at two sides of both of the second recess 214, and an second engaging groove 215 is respectively formed at two side edges of the upper face for being engaged with the second cover 213. Moreover, second recess 214 of the second base 210 is used for accepting the second ferrite core 212, and the through aperture 217 is used for accepting the plurality of second terminals 211. The terminal 211 are placed through the through apertures 217 and wrapped by conducting wires 2120 between the second ferrite core 212. The second cover 213 is a U-shaped rectangle body and engages with the second engaging groove 215 of the second base 210. After the main ferrite core module 20 and the sub ferrite core module 21 are assembled, a top portion of the sub ferrite core module 21 is engaged with the first recess 205 of the main ferrite core module 20 to form a modularized signal filter. Therefore, there is no need for utilizing the PCB as the carrier body, the design of the present invention utilizes over-lapping design to reduce the noise of the filtered signals and increase the effect of the filtered signals.

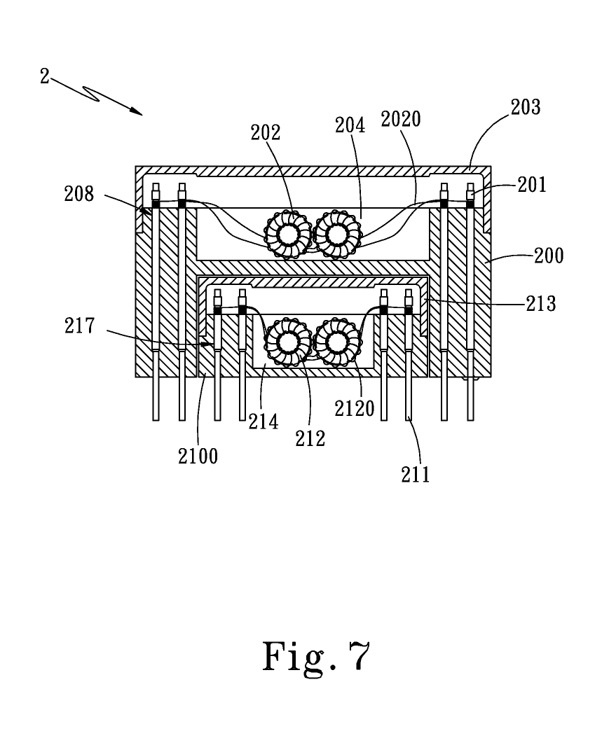

Please refer to FIG. 6 and FIG. 7. FIG. 6 is a cross-sectional view of the modularized signal filter of an embodiment according to the present invention. FIG. 7 is a combination cross-sectional view of the modularized signal filter of embodiment according to the present invention. The signal filter 2 is assembled by engaging the main ferrite core module 20 and the sub ferrite core module 21 together. The first recesses 204, 205 are formed on the first base 200 of the main ferrite core module 20, and the plurality of tubular through apertures 208 are formed at two sides of the first recesses 204, 205. Furthermore, the first terminal 201 is placed through the through aperture 208, and both ends of the first terminal 201 extend out of the first base 200. The first recess 204 is used for accepting the plurality of first ferrite cores 202, the first ferrite core 202 is wrapped by the conducting wire 2020, and one end of the conducting wire 2020 is wrapped on one end of the terminal 201. The first cover 203 is disposed to cover the top face of the first base 200. The second recess 214 is formed on the second base 210 of the sub ferrite core module 21, and the plurality of tubular through apertures 217 are formed at two sides of the second recess 214. The terminal 211 is placed through the through aperture 217, and both ends of the terminal 211 extend out of the second base 210. The second recess 214 is used for accepting the plurality of second ferrite cores 212, the second ferrite core 212 is wrapped by the conducting wire 2120, and one end of the conducting wire 2120 is wrapped on one end of the terminal 211. The second cover 213 is disposed to cover the top face of the second base 210. The first recess 205 of the first base 200 of the main ferrite core module 20 engages with the sub ferrite core module 21 to form the modularized signal filter.

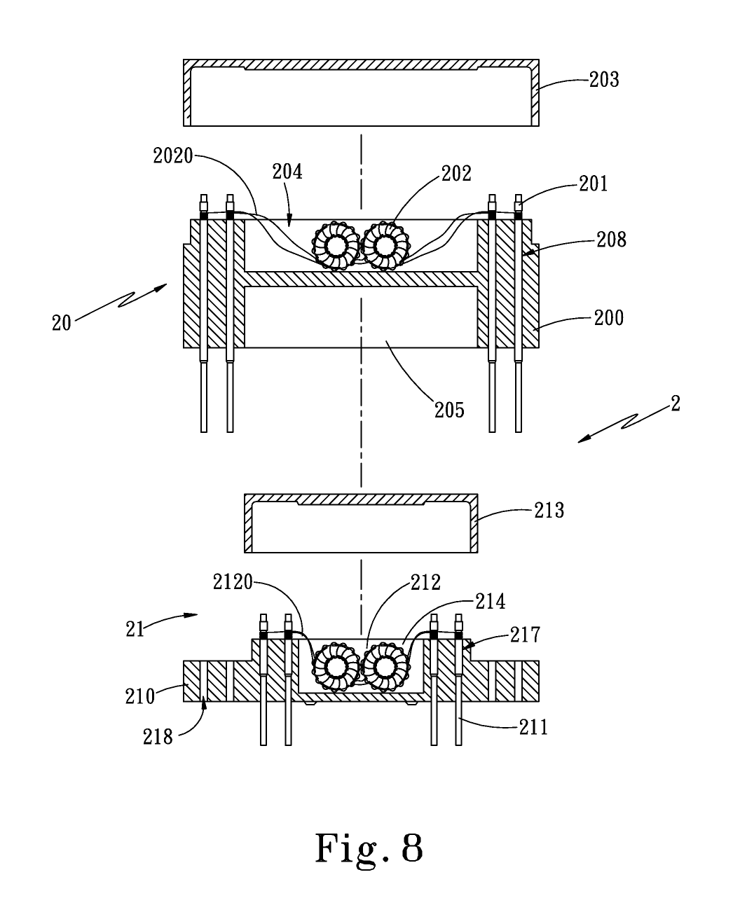

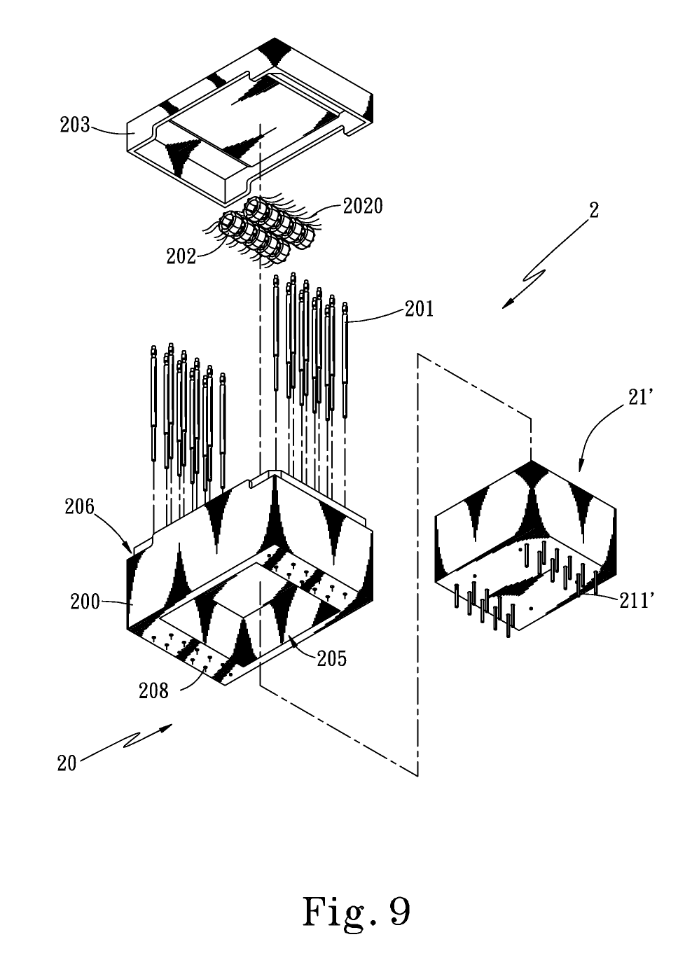

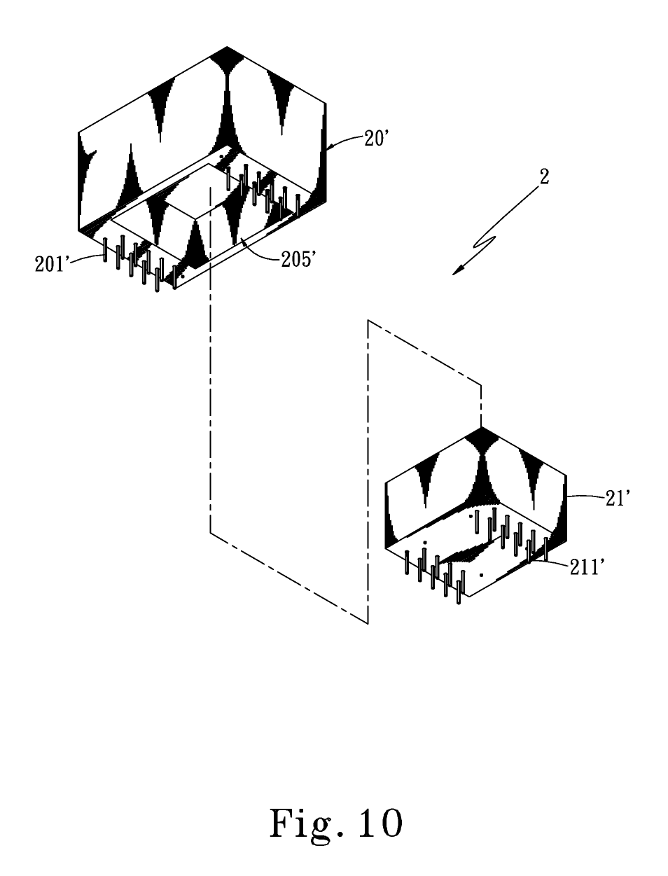

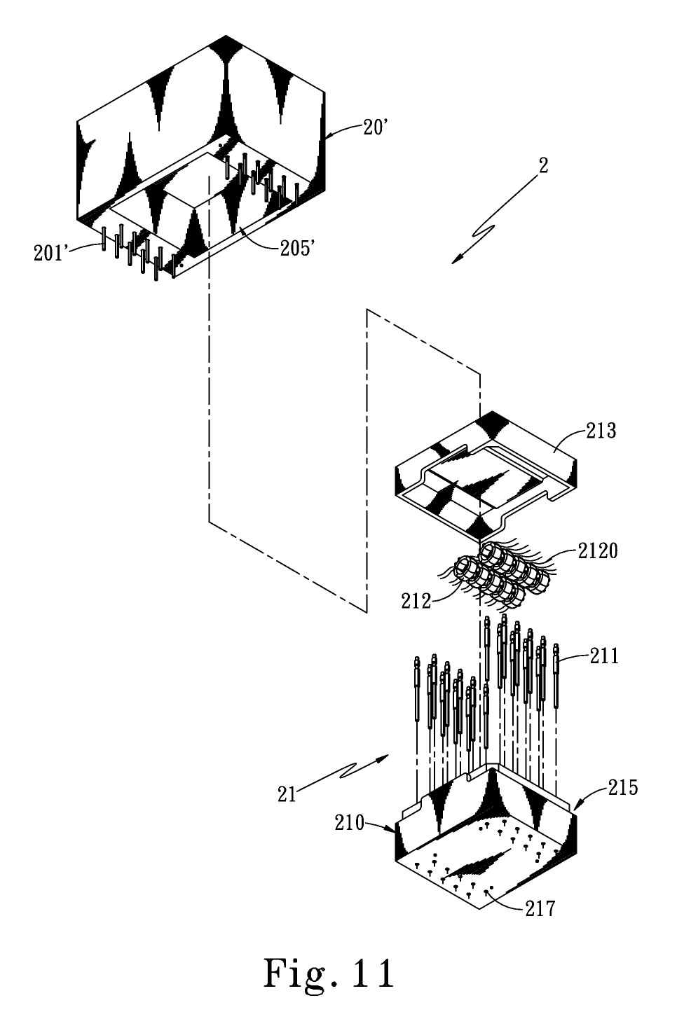

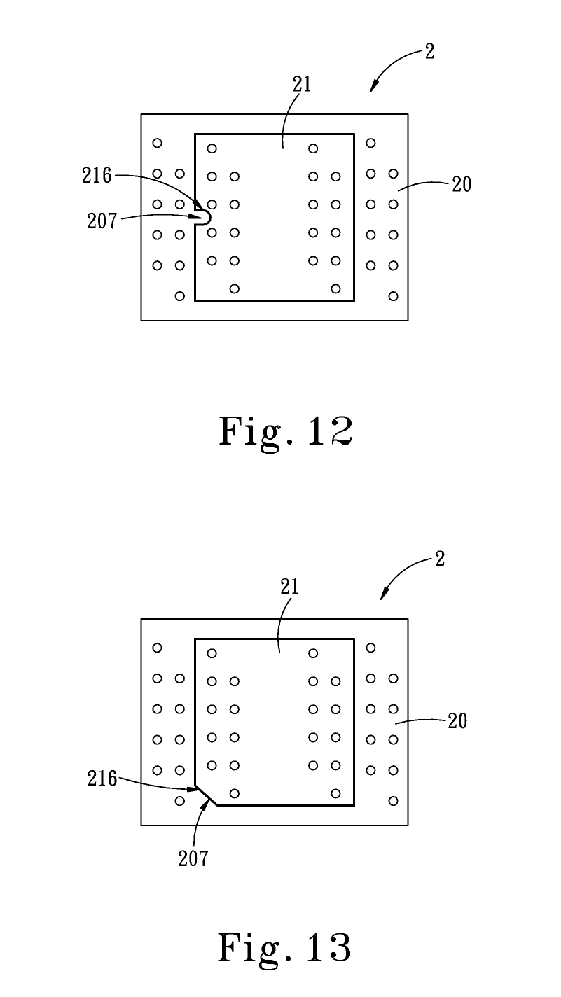

Please refer to FIG. 8, FIG. 9, FIG. 10, FIG. 11, FIG. 12, and FIG. 13 together. As shown in FIG. 8, the signal filter 2 is assembled by a main ferrite core module 20 and the sub ferrite core module 21, and the main and sub ferrite core modules 20, 21 respectively comprise the first and second covers 203, 213, the first and second bases 200, 210, the plurality of first and second ferrite cores 202, 212 and the plurality of first and second terminals 201, 211. In the preferred embodiment, two sides of the second base 210 of the sub ferrite core module 21 has the plurality of through apertures 218, the main ferrite core module 20 has a more impacted height such that the first terminal 201 of the main ferrite core module 20 can be correspondingly inserted into the through aperture 218 of the sub ferrite core module 21. With the positioning effect provided by the terminals 201, the main and sub ferrite core modules 20, 21 can be engaged security and preciously.

As shown in FIG. 9, FIG. 10, FIG. 11, FIG. 12, and FIG. 13. The signal filter 2 is assembled by a main ferrite core module 20 and the sub ferrite core module 21, and the main and sub ferrite core modules 20, 21 respectively comprise the first and second covers 203, 213, the first and second bases 200, 210 (please refer to FIG. 5.). Alternatively, as shown in FIG. 9, the main ferrite core module 20 is assembled with the first cover 203, the first base 200, the first ferrite core 202, the first terminal 201 and the integrated sub ferrite core module 21′ which includes the first ferrite core 202 and the terminal 211′, and the sub ferrite core module 21′ is engaged in the first recess 205 of the main ferrite core module 20 to form the signal filter 2.

As shown in FIG. 10, the integrated main ferrite core module 20′ and the integrated sub ferrite core module 21′ respectively have the ferrite cores 202′, 212′ and the terminals 201′, 211′, and the sub ferrite core module 21′ is engaged in the first recess 205′ of the main ferrite core module 20′ to form the signal filter 2.

As shown in FIG. 11, alternatively, the integrated main ferrite core module 20′ includes the ferrite core and the terminals 201′, the sub ferrite core module 21 is assembled by the second cover 213, the second base 210, second ferrite core 212, and the terminal 211, and the sub ferrite core module is engaged in the first recess 205′ of the main ferrite core module 20′ to form the signal filter 2.

Furthermore, as shown in FIG. 12 and FIG. 13. The signal filter 2 is assembled by a main ferrite core module 20 and the sub ferrite core module 21, in order to assembly the signal filter 2 correctly, a first engaging portion 207 and a second engaging portion 216 is respectively formed on one side of the first recess 205 of the main ferrite core module 20 and one corresponding side of the second base 210 of the sub ferrite core module 21 as an dummy-proof mechanism.

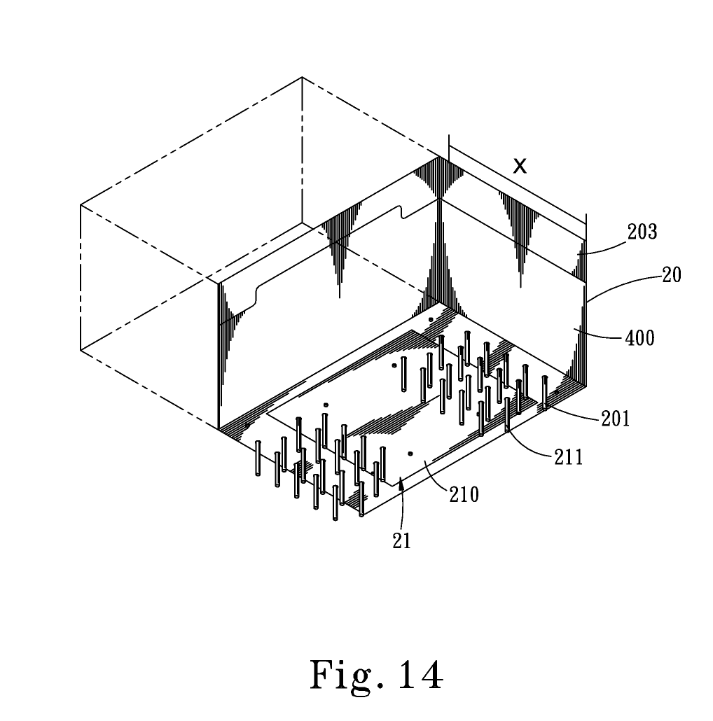

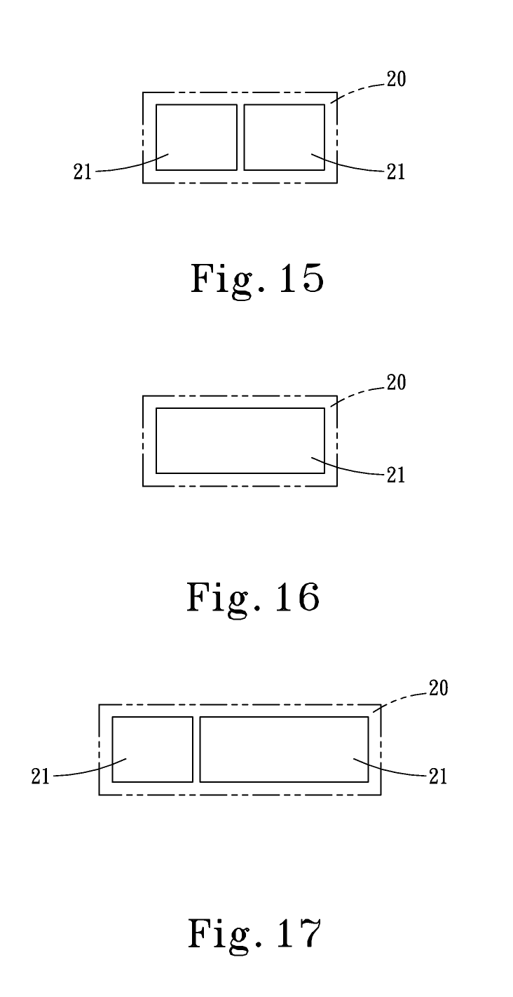

Moreover, please refer to FIG. 14, FIG. 15, FIG. 16, and FIG. 17. The signal filter 2 is assembled by a main ferrite core module 20 and the sub ferrite core module 21. In actual assembly, for different devices, different numbers of signal filter 2 might be applied; wherein a width X of the signal filter 2 (as shown in FIG. 14) can be various when the signal filter 2 is assembled with one or more than one the sub ferrite core module 21 and one main ferrite core module 20. Furthermore, the main and sub ferrite core modules with different X can be combined randomly (as shown in FIG. 15, FIG. 16, and FIG. 17) for different requirements.

Although the present invention has been explained in relation to its preferred embodiment, it is to be understood that many other possible modifications and variations can be made without departing from the spirit and scope of the invention as hereinafter claimed.

What is claimed is:

1. A modularized signal filter comprising:
a main ferrite core module having a first base, a first cover, a plurality of first ferrite cores, a plurality of first terminals and a recess disposed inside thereof; and
a sub ferrite core module having a second base, a second cover, a plurality of second ferrite cores, and a plurality of second terminals, capable of being assembled with the main ferrite core module;
wherein the signal filter is assembled with the main and sub ferrite core module, and first and second terminals are parallel disposed on two sides.

2. The modularized signal filter as claimed in claim 1, wherein the first base of the main ferrite core module has a plurality of recesses and a plurality of through apertures.

3. The modularized signal filter as claimed in claim 1, wherein a portion of the first base of the main ferrite core module has a first engaging portion.

4. The modularized signal filter as claimed in claim 1, wherein the second base the sub ferrite core module has a recess and a plurality of through apertures.

5. The modularized signal filter as claimed in claim 1, wherein the second base of the sub ferrite core module has a second engaging portion.

6. The modularized signal filter as claimed in claim 1, wherein the width of the main ferrite core module and the sub ferrite core module can be adjusted accordingly.

7. The modularized signal filter as claimed in claim 1, wherein the signal filter comprises one or more than one combination of the sub ferrite core module and the main ferrite core module.
